(19) United States
(12) Patent Application Publication
(10) Pub. No.: US 2024/0224808 A1
(43) Pub. Date: Jul. 4, 2024

(54) PIEZOELECTRIC THIN-FILM ELEMENT, MICROELECTROMECHANICAL SYSTEM, AND ULTRASOUND TRANSDUCER

(71) Applicant: TDK Corporation, Chou-ku, Tokyo (JP)

(72) Inventor: Yusuke SATO, Chuo-ku, Tokyo (JP)

(73) Assignee: TDK Corporation, Chuo-ku, Tokyo (JP)

(21) Appl. No.: 18/288,973

(22) PCT Filed: May 9, 2022
(86) PCT No.: PCT/JP2022/019714

§ 371 Date: Oct. 30, 2023

(30) Foreign Application Priority Data
Jun. 3, 2021 (JP) 2021-093659

(51) Int. Cl. H10N 30/853; B06B 1/06; C04B 35/26; C04B 35/475; C04B 37/02; H10N 30/00

(52) U.S. Cl. CPC H10N 30/8561; B06B 1/0666; C04B 35/26; C04B 35/475; C04B 37/023; H10N 30/10516; C04B 2235/3236; C04B 2235/3274; C04B 2237/06; C04B 2237/346; C04B 2237/40

(57) ABSTRACT

A piezoelectric thin-film element includes a first electrode layer, a piezoelectric thin film stacked on the first electrode layer, and a second electrode layer stacked on the piezoelectric thin film. A performance index P of the piezoelectric thin film is defined as (d_{33,f})²×Y/ε. d_{33,f} is a piezoelectric strain constant of thickness longitudinal vibration of the piezoelectric thin film. Y is a Young's modulus of the piezoelectric thin film. ε is a permittivity of the piezoelectric thin film. The performance index P is from 10% to 80.1%.

### TECHNICAL FIELD

The present disclosure relates to a piezoelectric thin-film element, a microelectromechanical system, and an ultrasonic transducer.

### BACKGROUND ART

Piezoelectric materials are processed into various piezoelectric elements in correspondence with various purposes. For example, a piezoelectric actuator converts a voltage into a force due to an inverse piezoelectric effect of deforming a piezoelectric material when a voltage is added to the piezoelectric material. In addition, a piezoelectric sensor converts a force into a voltage due to a piezoelectric effect of deforming a piezoelectric material when a pressure is added to the piezoelectric material. These piezoelectric elements are mounted on various electronic devices. In recent markets, since a reduction in size of electronic devices and an improvement of performance are required, piezoelectric elements (piezoelectric thin-film elements) using piezoelectric thin films are actively studied. However, the thinner the piezoelectric materials are, the less the piezoelectric effect and the inverse piezoelectric effect are likely to be obtained. Therefore, development of piezoelectric materials having excellent piezoelectric properties in a thin film state is expected.

In the related art, lead titanate (PbTiO₃) or lead zirconate titanate (Pb(Zr,TiO₃) having a perovskite structure have been frequently used in piezoelectric thin-film elements. For example, the following Non-Patent Literature 1 discloses a transducer using an epitaxial thin film consisting of lead titanate. The following Non-Patent Literature 1 also discloses that ultrasonic waves in a GHz band generated in thickness longitudinal vibration mode of an epitaxial thin film consisting of lead titanate are used in fingerprint imaging. However, since lead titanate and lead zirconate titanate contain lead that is harmful to a human body and an environment, development of a lead-free piezoelectric material is expected. For example, the following Patent Literature 1 discloses a metal oxide which has a perovskite structure and contains bismuth, potassium, titanium, iron, and an element M, the element M being at least one kind between magnesium and nickel as piezoelectric materials constituting the piezoelectric thin film.

### CITATION LIST

### Patent Literature

Patent Literature 1: Japanese Unexamined Patent Publication No. 2020-113649

### Non Patent Literature

Sato et al, Epitaxial PbTiO₃ ultrasonic transducer for fingerprint imaging in the giga-hertz range using the reflectometry of back side of substrate, Extended Abstracts of the 68th JSAP Spring Meeting, issued on Feb. 26, 2021, p01-073

### SUMMARY OF INVENTION

### Technical Problem

In correspondence with an increase in a demand for high-precision sensing and high communication speed, a resonance frequency in a high-frequency band (for example, a GHz band) is required for piezoelectric thin-film elements used in sensors, communication devices, and the like. The resonance frequency increases in accordance with a reduction in a thickness of a piezoelectric thin film. However, in a case of a piezoelectric thin-film element using a piezoelectric material such as lead titanate or lead zirconate titanate in the related art, in accordance with a reduction in the thickness of the piezoelectric thin film, piezoelectric properties (ferroelectricity) of the piezoelectric thin film are likely to deteriorate, and a dielectric loss (tanδ) of the piezoelectric thin-film element is likely to increase. For example, the deterioration of the piezoelectric properties (ferroelectricity) of the piezoelectric thin film in accordance with a reduction in the thickness of the piezoelectric thin film is caused by a dead layer at an interface of an electrode layer and the piezoelectric thin film, a size effect, and the like. From the above-described reasons, it is difficult to use the piezoelectric thin-film element using the piezoelectric material in the related art at a high-frequency band (for example, a GHz band).

An object of an aspect of the present invention is to provide a piezoelectric thin-film element that has a high resonance frequency and suppresses a dielectric loss, a micro electro mechanical system (MEMS) including the piezoelectric thin-film element, and an ultrasonic transducer including the piezoelectric thin-film element.

### Solution to Problem

For example, the invention relates to the following [1] to [10].
[1] A piezoelectric thin-film element, including:
   a first electrode layer;
   a piezoelectric thin film stacked on the first electrode layer; and
   a second electrode layer stacked on the piezoelectric thin film,
   wherein a performance index P of the piezoelectric thin film is defined as (d_{33.f})²×Y/ε,
   d_{33.f} is a piezoelectric strain constant of thickness longitudinal vibration of the piezoelectric thin film,
   Y is a Young's modulus of the piezoelectric thin film,
   ε is a permittivity of the piezoelectric thin film, and
   the performance index P is from 10% to 80.1%.
[2] The piezoelectric thin-film element according to [1],
   wherein −e_{31,f}/e₃₃ of the piezoelectric thin film is more than 0 and 0.80 or less.
[3] The piezoelectric thin-film element according to [1] or [2], further including:
   at least one intermediate layer,
   wherein the intermediate layer is disposed between the first electrode layer and the piezoelectric thin film, and
   the intermediate layer contains at least one between SrRuO₃ and LaNiO₃.
[4] The piezoelectric thin-film element according to any one of [1] to [3],
   wherein the piezoelectric thin film contains a metal oxide having a perovskite structure,
   the metal oxide contains bismuth, potassium, titanium, iron, and an element M, and
   the element M is at least one element between magnesium and nickel.
[5] The piezoelectric thin-film element according to [4],
   wherein the piezoelectric thin film contains a tetragonal crystal of the metal oxide, and
   a (001) plane of the tetragonal crystal is oriented in a thickness direction of the piezoelectric thin film.
[6] The piezoelectric thin-film element according to [5],
   wherein an interval of the (001) plane of the tetragonal crystal is c,
   an interval of a (100) plane of the tetragonal crystal is a, and c/a is from 1.05 to 1.20.
[7] The piezoelectric thin-film element according to any one of [1] to [6],
   wherein a thickness of the piezoelectric thin film is from 0.3 μm to 10 μm.
[8] The piezoelectric thin-film element according to any one of [1] to [7],
   wherein a resonance frequency of the thickness longitudinal vibration of the piezoelectric thin film is from 0.10 GHz to 2 GHz.
[9] A microelectromechanical system, including:
   the piezoelectric thin-film element according to any one of [1] to [8].
[10] An ultrasonic transducer, including:
   the piezoelectric thin-film element according to any one of [1] to [8].

### Advantageous Effects of Invention

According to an aspect of the invention, a piezoelectric thin-film element that has a high resonance frequency and suppresses a dielectric loss, a micro electro mechanical system (MEMS) including the piezoelectric thin-film element, and an ultrasonic transducer including the piezoelectric thin-film element are provided.

### BRIEF DESCRIPTION OF DRAWINGS

FIG. 1(a) is a schematic cross-sectional view of a piezoelectric thin-film element according to an embodiment of the invention, FIG. 1(b) is an exploded perspective view of the piezoelectric thin-film element illustrated in FIG. 1(a), and in FIG. 1(b), a substrate, a first intermediate layer, a second intermediate layer, and a second electrode layer are omitted.

FIG. 2 is a perspective view of a unit cell of a metal oxide (tetragonal crystal) having a perovskite structure and illustrates an arrangement of respective elements in the perovskite structure.

FIG. 3 is a perspective view of a unit cell of a metal oxide (tetragonal crystal) having a perovskite structure and illustrates a crystal plane and a crystal orientation of the tetragonal crystal.

FIG. 4 is a three-dimensional coordinate system for illustrating a composition of a piezoelectric thin film.

FIG. 5 is a trigonal coordinate system corresponding to a triangle illustrated in FIG. 4.

FIG. 6 is a schematic cross-sectional view of a piezoelectric thin-film element (ultrasonic transducer) according to another embodiment of the invention.

### DESCRIPTION OF EMBODIMENTS

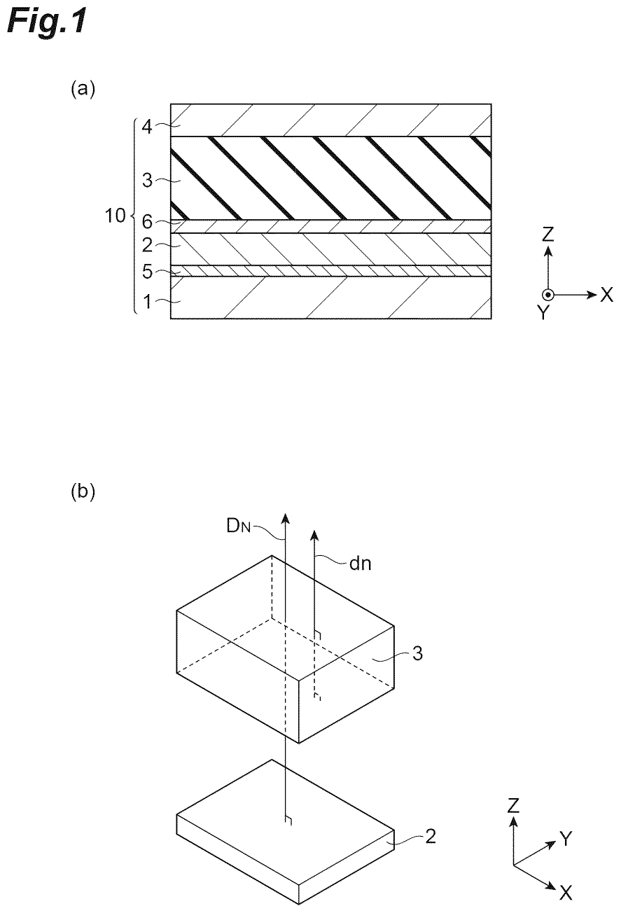

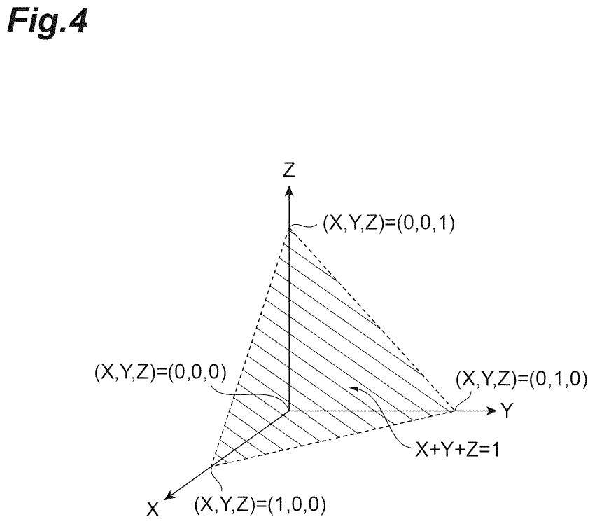

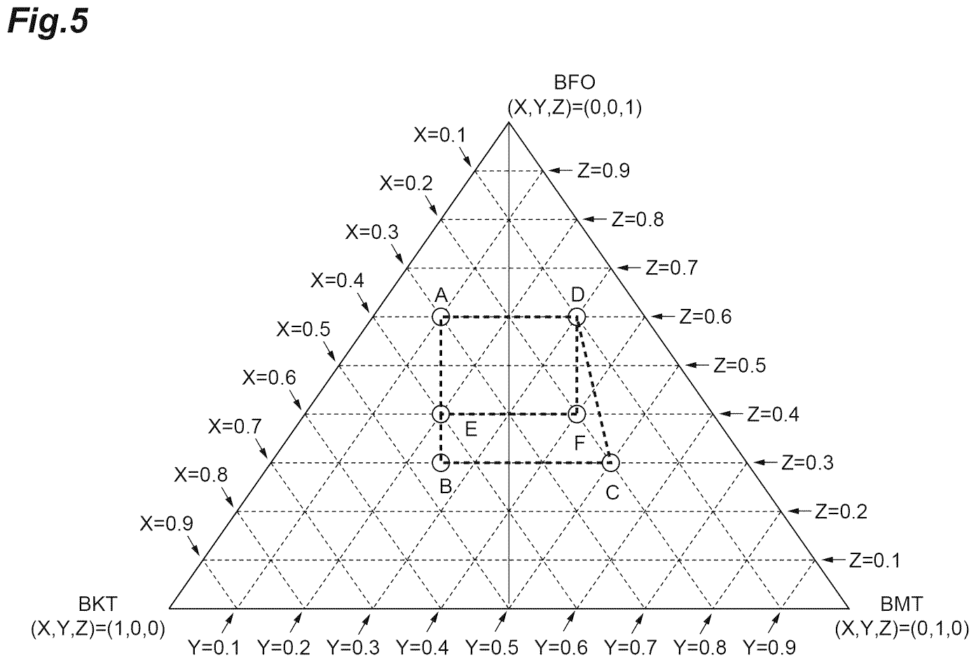

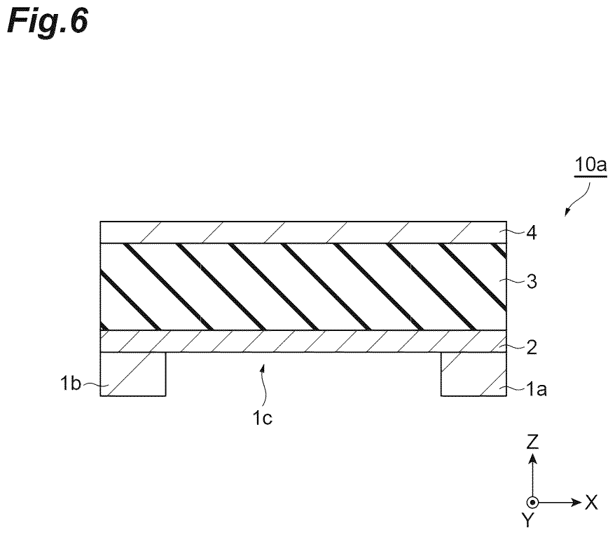

Hereinafter, a preferred embodiment of the invention will be described in detail with reference to the accompanying drawings. However, the invention is not limited to the following embodiment. In the drawings, the same reference numerals will be given to the same or equivalent elements. An X-axis, a Y-axis, and a Z-axis shown in FIG. 1(a), FIG. 1(b), and FIG. 6 are three coordinate axes orthogonal to each other. The X-axis, the Y-axis, and the Z-axis are common to FIG. 1(a), FIG. 1(b), and FIG. 6, but coordinate systems shown in FIG. 1(a), FIG. 1(b), and FIG. 6 have absolutely no relation to coordinate systems shown in FIG. 4 and FIG. 5.

### (Piezoelectric Thin-Film Element)

A piezoelectric thin-film element according to this embodiment includes a first electrode layer, a piezoelectric thin film that is directly or indirectly stacked on the first electrode layer, and a second electrode layer that is directly or indirectly stacked on the piezoelectric thin film. For example, as illustrated in FIG. 1(a), a piezoelectric thin-film element 10 according to this embodiment may include a single crystal substrate 1, a first electrode layer 2 (lower electrode layer) that is stacked on the single crystal substrate 1, a piezoelectric thin film 3 that is stacked on the first electrode layer 2, and a second electrode layer 4 (upper electrode layer) that is stacked on the piezoelectric thin film 3. The piezoelectric thin-film element 10 may further include at least one intermediate layer. For example, the piezoelectric thin-film element 10 may include a first intermediate layer 5. The first intermediate layer 5 may be disposed between the single crystal substrate 1 and the first electrode layer 2, and the first electrode layer 2 may be directly stacked on a surface of the first intermediate layer 5. The piezoelectric thin-film element 10 may include a second intermediate layer 6. The second intermediate layer 6 may be disposed between the first electrode layer 2 and the piezoelectric thin film 3, and the piezoelectric thin film 3 may be directly stacked on a surface of the second intermediate layer 6. A thickness of each of the single crystal substrate 1, the first intermediate layer 5, the first electrode layer 2, the second intermediate layer 6, the piezoelectric thin film 3, and the second electrode layer 4 may be uniform. As illustrated in FIG. 1(b), a thickness direction dn of the piezoelectric thin film 3 is approximately parallel to a normal direction DN of a surface of the first electrode layer 2. That is, a surface of the piezoelectric thin film 3 is approximately parallel to the surface of the first electrode layer 2. The thickness direction dn of the piezoelectric thin film 3 is a polarization direction of the piezoelectric thin film 3. The thickness direction dn of the piezoelectric thin film 3 may also be referred to as a normal direction of the surface of the piezoelectric thin film 3.

A modification example of the piezoelectric thin-film element 10 does not have to include the single crystal substrate 1. For example, after forming the first electrode layer 2, the piezoelectric thin film 3, and the second electrode layer 4, the single crystal substrate 1 may be removed. In a case where the single crystal substrate 1 functions as an electrode, the single crystal substrate 1 may be the first electrode layer 2. That is, in a case where the single crystal substrate 1 functions as an electrode, the modification example of the piezoelectric thin-film element 10 may include the single crystal substrate 1 and the piezoelectric thin film 3 that is stacked on the single crystal substrate 1. The piezoelectric thin film 3 may be directly stacked on the single crystal substrate 1. The piezoelectric thin film 3 may be stacked on the single crystal substrate 1 through at least one intermediate layer between the first intermediate layer 5 and the second intermediate layer 6.

A resonance frequency of thickness longitudinal vibration of the piezoelectric thin film 3 may be from 0.10 GHz to 2 GHZ, from 0.17 GHz to 2 GHz, from 0.3 GHz to 2 GHz, or from 0.17 GHz to 1.17 GHz. A performance index P of the piezoelectric thin film 3 is defined as (d_{33.f})²×Y/ε. The performance index P has a technical significance similar to kt² that is a square of an electromechanical coupling coefficient. d_{33.f} is a piezoelectric strain constant of thickness longitudinal vibration of the piezoelectric thin film 3. Y is a Young's modulus of the piezoelectric thin film 3. ε is a permittivity of the piezoelectric thin film 3. The performance index P is from 10% to 80.1%. That is, 100×(d_{33,f})²×Y/ε is from 10 to 80. The performance index P is a dimensionless numerical value. A unit of the piezoelectric strain constant d_{33.f} is [pm/V] or [pC/N]. A unit of the Young's modulus Y is [GPa] or [N/m²]. A unit of the permittivity ε is [F·m⁻¹], [C/V·m], or [C²/N·m²]. ε is equal to 80×ε33. 80 is a permittivity of vacuum. ε₃₃ is a relative permittivity (εᵣ) of the piezoelectric thin film 3. The resonance frequency of the thickness longitudinal vibration in the piezoelectric thin film 3 may be from 0.03 GHz to 2 GHz.

For example, the piezoelectric strain constant d_{33.f} may be from 40 pm/V to 120 pm/V, 40 pm/V to 91 pm/V, from 47 pm/V to 91 pm/V, or from 47 pm/V to 90 pm/V. For example, the Young's modulus Y may be from 50 GPa to 200 GPa, from 70 GPa to 100 GPa, or from 76 GPa to 94 GPa. For example, the relative permittivity ε₃₃ may be from 50 to 200 or from 87 to 155. In a case where each of d_{33.f}, Y, and 833 is within the above-described range, the performance index P is likely to be from 10% to 80.1%. The performance index P may be from 15.1% to 80.1%.

Since the piezoelectric thin-film element 10 uses the thickness longitudinal vibration (bulk elastic wave) of the piezoelectric thin film 3, the piezoelectric thin-film element 10 can act at a high resonance frequency (a resonance frequency in a sub-GHz band or a resonance frequency in a GHz band). Accordingly, the piezoelectric thin-film element 10 is applicable to a high-precision sensor (for example, an ultrasonic transducer such as a fingerprint sensor and a vascular sensor), a high-speed communication device, or the like. In contrast, a resonance frequency of a piezoelectric thin-film element in the related art, using length transverse vibration (in-plane vibration) of the piezoelectric thin film, is relatively low and is a MHz band.

In a case where the performance index P is from 10% to 80.1%, an increase in a dielectric loss (tanδ) of the piezoelectric thin-film element 10 in accordance with a decrease in a thickness of the piezoelectric thin film 3 is suppressed. That is, even in a case where the piezoelectric thin film 3 is very thin, the dielectric loss in a high-frequency band (for example, a frequency band of from 0.10 GHz to 2 GHz) can be sufficiently suppressed. As a result, the thickness of the piezoelectric thin film 3 can be set to a very small value and the resonance frequency of the thickness longitudinal vibration of the piezoelectric thin film 3 can be set within a high-frequency band. For example, the thickness of the piezoelectric thin film 3 may be from 0.3 μm to 5 μm, from 0.3 μm to 3 μm, from 0.5 μm to 5 μm, or from 0.5 μm to 3 μm. According to this embodiment, even when the thickness of the piezoelectric thin film 3 is 5 μm or less or 3 μm or less, sufficient piezoelectric properties (ferroelectricity) of the piezoelectric thin film 3 are maintained and the dielectric loss in a high-frequency band is suppressed, and thus the resonance frequency of the thickness longitudinal vibration of the piezoelectric thin film 3 can be set within a high-frequency band. In a case where the performance index P is less than 10%, the dielectric loss in a high-frequency band is less likely to be suppressed. For example, the dielectric loss (tanδ) of the piezoelectric thin-film element 10 may be from 0.0% to 0.9% or from 0.3% to 0.9%.

−e_{31,f}/e₃₃ of the piezoelectric thin film 3 may be more than 0 and 0.80 or less, from 0.70 to 0.80, or more than 0 and 0.70 or less. −e_{31,f} is a piezoelectric stress constant of length transverse vibration (in-plane vibration) of the piezoelectric thin film 3. A unit of −e_{31,f} is [C/m²]. The length transverse vibration is vibration (expansion and contraction) of the piezoelectric thin film 3 in a direction orthogonal to a polarization direction (thickness direction dn) of the piezoelectric thin film 3. In other words, the length transverse vibration is vibration (expansion and contraction) of the piezoelectric thin film 3 in a direction that is approximately parallel to a surface of each of the first electrode layer 2 and the second electrode layer 4. e₃₃ is a piezoelectric stress constant of thickness longitudinal vibration of the piezoelectric thin film 3. A unit of e₃₃ is [C/m²]. The thickness longitudinal vibration is vibration (expansion and contraction) of the piezoelectric thin film in the polarization direction (thickness direction dn) of the piezoelectric thin film 3. In other words, the thickness longitudinal vibration is vibration (expansion and contraction) of the piezoelectric thin film 3 in the normal direction DN of the surface of the first electrode layer 2. e₃₃ may be calculated from a measurement value of each of d_{33.f} and Y.

The smaller −e_{31,f}/e₃₃ is, the further the length transverse vibration (in-plane vibration) of the piezoelectric thin film 3 is suppressed, and the more the thickness longitudinal vibration of the piezoelectric thin film 3 is likely to occur. −e_{31,f}/e₃₃ being 0.80 or less indicates that the length transverse vibration (in-plane vibration) of the piezoelectric thin film 3 is sufficiently suppressed in comparison to the thickness longitudinal vibration of the piezoelectric thin film 3. That is, in a case where −e_{31,f}/e₃₃ is 0.80 or less, the in-plane vibration that is a main cause for a noise in a high-frequency band is likely to be suppressed. In a case where the performance index P is from 10% to 80.1%, −e_{31,f}/e₃₃ tends to be more than 0 and 0.80 or less.

A lattice stress that is approximately orthogonal to the thickness direction dn of the piezoelectric thin film 3 may act on the piezoelectric thin film 3. The lattice stress may be caused by lattice mismatching between the first electrode layer 2 and the piezoelectric thin film 3. For example, in a case where a lattice constant of the first electrode layer 2 in an in-plane direction of the first electrode layer 2 (direction that is approximately parallel to the surface of the first electrode layer 2) is smaller than a lattice constant of the piezoelectric thin film 3 in the same direction (direction that is approximately orthogonal to the thickness direction dn of the piezoelectric thin film 3), a lattice stress compressing the piezoelectric thin film 3 in the direction that is approximately orthogonal to the thickness direction dn is likely to act on the piezoelectric thin film 3. In accordance with cooling-down of the piezoelectric thin film 3 during a process of forming the piezoelectric thin film 3, a thermal stress contacting the piezoelectric thin film 3 in the direction that is approximately orthogonal to the thickness direction dn may act on the piezoelectric thin film 3. On the other hand, in a case where the lattice constant of the first electrode layer 2 in the in-plane direction of the first electrode layer 2 (direction that is approximately parallel to the surface of the first electrode layer 2) is larger than the lattice constant of the piezoelectric thin film 3 in the same direction (direction that is approximately orthogonal to the thickness direction dn of the piezoelectric thin film 3), a lattice stress pulling the piezoelectric thin film 3 in the direction that is approximately orthogonal to the thickness direction dn is likely to act on the piezoelectric thin film 3.

The lattice stress may be caused by lattice mismatching between the second intermediate layer 6 and the piezoelectric thin film 3. For example, in a case where a lattice constant of the second intermediate layer 6 in the in-plane direction of the first electrode layer 2 (direction that is approximately parallel to the surface of the first electrode layer 2) is smaller than the lattice constant of the piezoelectric thin film 3 in the same direction (direction that is approximately orthogonal to the thickness direction dn of the piezoelectric thin film 3), a lattice stress compressing the piezoelectric thin film 3 in the direction that is approximately orthogonal to the thickness direction dn is likely to act on the piezoelectric thin film 3. On the other hand, in a case where the lattice constant of the second intermediate layer 6 in the in-plane direction of the first electrode layer 2 (direction that is approximately parallel to the surface of the first electrode layer 2) is larger than the lattice constant of the piezoelectric thin film 3 in the same direction (direction that is approximately orthogonal to the thickness direction dn of the piezoelectric thin film 3), a lattice stress pulling the piezoelectric thin film 3 in the direction that is approximately orthogonal to the thickness direction dn is likely to act on the piezoelectric thin film 3.

The lattice stress suppresses expansion and contraction of the piezoelectric thin film 3 in a direction that is approximately orthogonal to the thickness direction dn of the piezoelectric thin film 3. Accordingly, the lattice stress suppresses the length transverse vibration (in-plane vibration) of the piezoelectric thin film 3.

On the other hand, the thickness longitudinal vibration of the piezoelectric thin film 3 is less likely to be suppressed by the lattice stress. In a case where the lattice stress compressing the piezoelectric thin film 3 in a direction that is approximately orthogonal to the thickness direction dn acts on the piezoelectric thin film 3, the piezoelectric thin film 3 is likely to be expanded in the thickness direction dn of the piezoelectric thin film 3. In other words, the crystal structure (perovskite structure) of the piezoelectric thin film 3 is likely to form a tetragonal crystal, and a (001) plane of the tetragonal crystal is likely to be oriented in the thickness direction dn of the piezoelectric thin film 3 due to the lattice stress. Accordingly, deterioration of the piezoelectric properties (ferroelectricity) of the piezoelectric thin film 3 in accordance with a decrease in the thickness of the piezoelectric thin film 3 is likely to be suppressed due to the lattice stress, and the dielectric loss is likely to be suppressed. In other words, elastic energy of the thickness longitudinal vibration of the piezoelectric thin film 3 is likely to be accumulated in the piezoelectric thin film 3 due to the lattice stress, and the performance index P (a value relating to Kt² that is the square of an electromechanical coupling coefficient) is likely to increase. From the above-described reasons, the resonance frequency of the thickness longitudinal vibration of the piezoelectric thin film 3 is likely to be set within a high-frequency band.

The piezoelectric thin film 3 may contain a metal oxide having a perovskite structure. For example, the metal oxide may contain at least two kinds of elements selected from the group consisting of bismuth (Bi), lanthanum (La), yttrium (Y), potassium (K), sodium (Na), lithium (Li), titanium (Ti), zirconium (Zr), magnesium (Mg), nickel (Ni), zinc (Zn), iron (Fe), manganese (Mn), cobalt (Co), and galium (Ga). From the viewpoint that the metal oxide is likely to form a tetragonal crystal, and that the piezoelectric thin film 3 is likely to have a high resonance frequency, a large d_{33.f} and a large performance index P, the metal oxide may contain Bi, K, Ti, Fe, and an element M. The element M may be at least one element between Mg and Ni. The metal oxide is a main component of the piezoelectric thin film 3. A ratio of all elements constituting the metal oxide in the piezoelectric thin film 3 may be from 99 mol % to 100 mol %. The piezoelectric thin film 3 may consist only of the metal oxide. As long as the piezoelectric properties of the piezoelectric thin film 3 do not deteriorate, the piezoelectric thin film 3 may contain other elements in addition to Bi, K, Ti, Fe, the element M, and O.

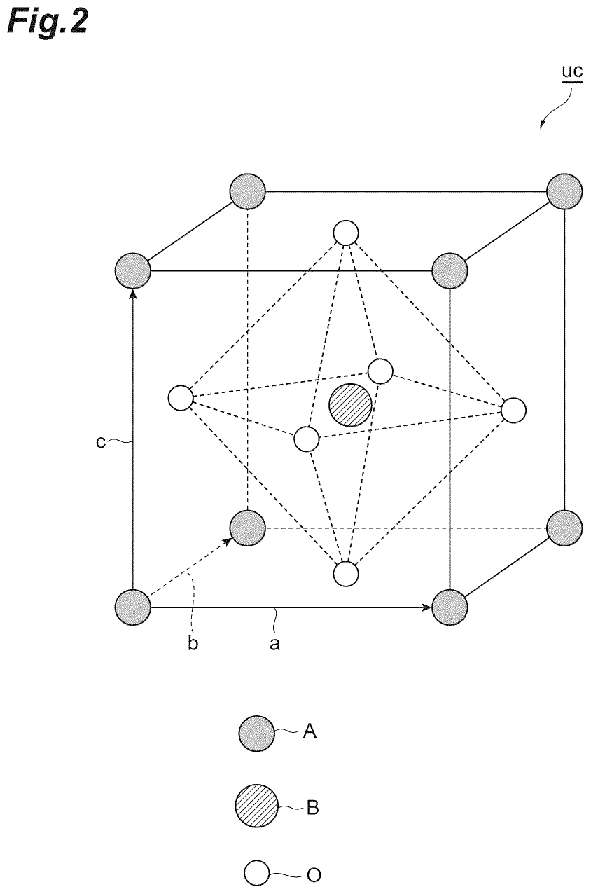

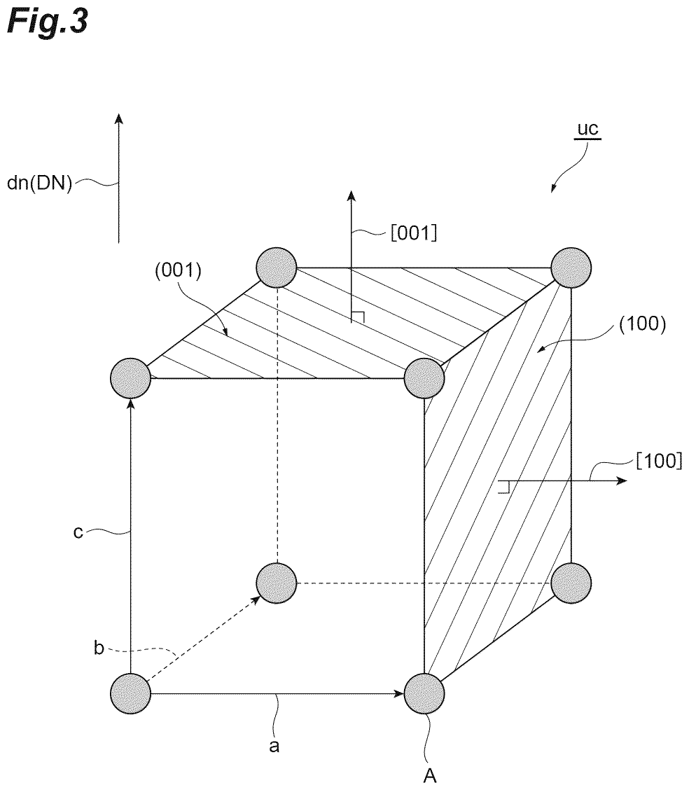

In the following description, the metal oxide having a perovskite structure is noted as “perovskite type oxide”. The piezoelectric thin film 3 may consist of a single crystal of the perovskite type oxide. The piezoelectric thin film 3 may consist of a polycrystal of the perovskite type oxide. A unit cell of the perovskite type oxide is illustrated in FIG. 2. An element located at an A site of a unit cell uc is Bi or K. An element located at a B site of the unit cell uc is Ti, Mg, Ni, or Fe. The unit cell uc illustrated in FIG. 2 is the same as a unit cell uc illustrated in FIG. 3. However, in FIG. 3, the B site and oxygen (O) in the unit cell uc are omitted to illustrate crystal planes. a is a lattice constant corresponding to an interval of a (100) plane of the perovskite type oxide. b is a lattice constant corresponding to an interval of a (010) plane of the perovskite type oxide. c is a lattice constant corresponding to an interval of a (001) plane of the perovskite type oxide.

The piezoelectric thin film 3 may contain a tetragonal crystal of the perovskite type oxide at an ordinary temperature or a temperature that is equal to or lower than a Curie temperature of the perovskite type oxide. As described above, since a lattice stress is likely to act on the piezoelectric thin film 3, the piezoelectric thin film 3 is likely to be contracted in a direction that is approximately orthogonal to the thickness direction dn. As a result, each of the lattice constants a and b of the piezoelectric thin film 3 is likely to be smaller than the lattice constant c in the thickness direction dn of the piezoelectric thin film 3, and the perovskite type oxide is likely to form a tetragonal crystal. As a result, the piezoelectric thin film 3 is likely to have excellent piezoelectric properties (ferroelectricity), and the piezoelectric thin film 3 is likely to have a high resonance frequency, a large d_{33.f}, and a large performance index P. All perovskite type oxides contained in the piezoelectric thin film 3 may be tetragonal crystals. The piezoelectric thin film 3 may further contain any one or both of a cubic crystal of the perovskite type oxide and a rhombohedral crystal of the perovskite type oxide in addition to the tetragonal crystal of the perovskite type oxide.

The (001) plane of the tetragonal crystal may be oriented in the thickness direction dn of the piezoelectric thin film 3. A direction in which the perovskite type oxide having the above-described composition is likely to be polarized is [001]. Accordingly, when the (001) plane of the tetragonal crystal is oriented in the thickness direction dn of the piezoelectric thin film 3, the piezoelectric thin film 3 is likely to have excellent piezoelectric properties (ferroelectricity), and the piezoelectric thin film 3 is likely to have a high resonance frequency, a large d_{33.f}, and a large performance index P. From the same reason, c/a of the tetragonal crystal may be from 1.05 to 1.20 or from 1.05 to 1.14. For example, the lattice constant a of the tetragonal crystal may be from 0.375 Å to 0.395 Å. For example, the lattice constant c of the tetragonal crystal may be from 0.430 Å to 0.450 Å. The lattice constant b of the tetragonal crystal is equal to the lattice constant a.

An extent of orientation of each crystal plane of the perovskite type oxide (tetragonal crystal) may be quantified by a degree of orientation. The degree of orientation of each crystal plane may be calculated on the basis of a peak of a diffracted X-ray derived from each crystal plane. The peak of the diffracted X-ray derived from each crystal plane may be measured by out-of-plane measurement on a surface of the piezoelectric thin film 3. The degree of orientation of a (001) plane may be expressed as 100×I₍₀₀₁₎/ΣI₍ₕₖ₁₎. The degree of orientation of a (110) plane may be expressed as 100×I₍₁₁₀₎/ΣI₍ₕₖ₁₎. The degree of orientation of a (111) plane may be expressed as 100×I₍₁₁₁₎/ΣI₍ₕₖ₁₎. I₍₀₀₁₎ is a maximum value of a peak of a diffracted X-ray derived from the (001) plane. I₍₁₁₀₎ is a maximum value of a peak of a diffracted X-ray derived from the (110) plane. I₍₁₁₁₎ is a maximum value of a peak of a diffracted X-ray derived from the (111) plane. ΣI₍ₕₖ₁₎ is I₍₀₀₁₎+I₍₁₁₀₎+I₍₁₁₁₎. The degree of orientation of the (001) plane may also be expressed as 100×S₍₀₀₁₎/ΣS₍ₕₖ₁₎. The degree of orientation of the (110) plane may also be expressed as 100×S₍₁₁₀₎/ΣS₍ₕₖ₁₎. The degree of orientation of the (111) plane may also be expressed as 100×S₍₁₁₁₎/ΣS₍ₕₖ₁₎. S₍₀₀₁₎ is an area of the peak (integration of the peak) of the diffracted X-ray derived from the (001) plane. S₍₁₁₀₎ is an area of the peak (integration of the peak) of the diffracted X-ray derived from the (110) plane. S₍₁₁₁₎ is an area of the peak (integration of the peak) of the diffracted X-ray derived from the (111) plane. ΣS₍ₕₖ₁₎ is S₍₀₀₁₎+S₍₁₁₀₎+S₍₁₁₁₎. The extent of orientation of each crystal plane may be quantified by the degree of orientation based on a Lotgering method.

From the viewpoint that the piezoelectric thin film 3 is likely to have a large d_{33.f} and a large performance index P, it is preferable that the (001) plane of the tetragonal crystal is preferentially oriented in the thickness direction dn of the piezoelectric thin film 3. That is, the degree of orientation of the (001) plane is preferably higher than the degree of orientation of each of the (110) plane and the (111) plane. For example, the degree of orientation of the (001) plane is from 70% to 100%, preferably from 80% to 100%, and more preferably 90% to 100%.

In contrast to the piezoelectric thin film 3, it is difficult to distort a bulk of a piezoelectric material having a cubic crystal structure or a pseudo cubic crystal structure in order to make the bulk of the piezoelectric material tetragonal crystal. Accordingly, the bulk of the piezoelectric material tends to be less likely to have piezoelectric properties caused by the tetragonal crystal of the perovskite type oxide.

A crystal orientation property described below indicates that the (001) plane of the tetragonal crystal is oriented in the thickness direction dn of the piezoelectric thin film 3.

The piezoelectric thin film 3 is likely to have the above-described crystal orientation property. A thin film is a crystalline film formed by a vapor deposition method or a solution method. On the other hand, a bulk of a piezoelectric material having the same composition as that of the piezoelectric thin film 3 tends to be less likely to have crystal orientation property in comparison to the piezoelectric thin film 3. The reason for this is that the bulk of the piezoelectric material is a sintered body (ceramics) of powders containing essential elements of the piezoelectric material, and that it is difficult to control a structure and an orientation of a plurality of crystals constituting the sintered body. A relative resistivity of the bulk of the piezoelectric material is lower than that of the piezoelectric thin film 3 because the bulk of the piezoelectric material contains Fe. As a result, a leak current is likely to occur in the bulk of the piezoelectric material. Accordingly, it is difficult to polarize the bulk of the piezoelectric material by applying a high electric field, and it is difficult for the bulk of the piezoelectric material to have similar piezoelectric properties as in the piezoelectric thin film.

The metal oxide contained in the piezoelectric thin film 3 may be expressed by the following Chemical Formula 1. The following Chemical Formula 1 is substantially the same as the following Chemical Formula 1a. In a case where the metal oxide is expressed by the following Chemical Formula 1, the metal oxide of the piezoelectric thin film 3 is likely to contain a tetragonal crystal, the tetragonal crystal is likely to have the above-described crystal orientation property, and the piezoelectric thin film 3 is likely to have a high resonance frequency, a large d_{33.f} and a large performance index P.

$$\\ \begin{matrix}x ( {Bi}_{α} {K}_{1 - α} ) {TiO}_{3} - y Bi ( {M}_{β} {Ti}_{1 - β} ) {O}_{3} - z {BiFeO}_{3} & ( 1 )\end{matrix}$$

$$\\ \begin{matrix}{( {Bi}_{α} {K}_{1 - α} )}_{x} {Bi}_{y + z} {{Ti}_{x} ( {M}_{β} {Ti}_{1 - β} )}_{y} {Fe}_{z} {O}_{3 \pm δ} & ( 1 a )\end{matrix}$$

Each of x, y, and z in the Chemical Formula 1 is a positive real number (unit: mol). x+y+z is 1. x in the Chemical Formula 1 is more than 0 and less than 1. y in the Chemical Formula 1 is more than 0 and less than 1. z in the Chemical Formula 1 is more than 0 and less than 1. a in the Chemical Formula 1 is more than 0 and less than 1. β in the Chemical Formula 1 is more than 0 and less than 1. For example, α may be 0.5, and β may be 0.5. M in the Chemical Formula 1 is expressed as Mg_{γ}Ni_{1-γ}. γ is from 0 to 1. A sum of the number of moles of Bi and K in the metal oxide may be expressed as [A], and a sum of the number of moles of Ti, Fe, and the element M in the metal oxide may be expressed as [B], and [A]/[B] may be 1.0. [A]/[B] may be a value other than 1.0 as long as the metal oxide can have a perovskite structure. That is, [A]/[B] may be less than 1.0, and may be more than 1.0. 8 in the Chemical Formula 1a is 0 or more. 8 may be a value other than 0 as long as the metal oxide can have a perovskite structure. For example, δ may be more than 0 and 1.0 or less. For example, δ may be calculated from a valency of each of an ion in the A site and an ion in the B site in the perovskite structure. The valency of each of the ions may be measured by an X-ray photoelectron spectroscopy (XPS) method.

In the following description, (Bi_{α}K_{1-α})TiO₃ is noted as BKT. Bi(M_{β}Ti_{1-β})O₃ is noted as BMT. BiFeO₃ is noted as BFO. A metal oxide having a composition expressed as the sum of BKT and BMT is noted as BKT-BMT. The metal oxide having a composition expressed as the Chemical Formula 1 is noted as xBKT-yBMT-zBFO. A Crystal of each of BKT, BMT, BFO, BKT-BMT, and xBKT-yBMT-zBFO has a perovskite structure.

The crystal of BKT is a tetragonal crystal at an ordinary temperature and BKT is a ferroelectric material. The crystal of BMT is a rhombohedral crystal at an ordinary temperature and BMT is a ferroelectric material. The crystal of BFO is a rhombohedral crystal at an ordinary temperature and BFO is a ferroelectric material. A thin film consisting of BKT-BMT is tetragonal crystal at an ordinary temperature. c/a of the tetragonal crystal of BKT-BMT tends to be larger than c/a of BKT. A thin film consisting of BKT-BMT is more excellent in ferroelectricity in comparison to the thin film consisting of BKT and the thin film consisting of BMT. A thin film consisting of xBKT-yBMT-zBFO tends to be tetragonal crystal at an ordinary temperature. c/a of the tetragonal crystal of xBKT-yBMT-zBFO tends to be larger than c/a of BKT-BMT. The thin film consisting of xBKT-yBMT-zBFO is more excellent in ferroelectricity in comparison to the thin film consisting of BKT-BMT. That is, the piezoelectric thin film 3 containing xBKT-yBMT-zBFO may be a ferroelectric thin film. It is inferred that the ferroelectricity of the piezoelectric thin film 3 is caused by a composition of xBKT-yBMT-zBFO having morphotropic phase boundary (MPB). However, since the piezoelectric thin film 3 belongs to a tetragonal crystal system, it is inferred that the ferroelectricity of the piezoelectric thin film 3 is not simply due to only MPB. When the piezoelectric thin film 3 has the ferroelectricity, the piezoelectric thin film 3 is likely to have a large d_{33.f}. In contrast to the piezoelectric thin film 3, a crystal included in a bulk of xBKT-yBMT-zBFO is a pseudo cubic crystal, and the bulk of xBKT-yBMT-zBFO tends to be less likely to have the crystal orientation property and the ferroelectricity in comparison to the piezoelectric thin film 3.

The composition of xBKT-yBMT-zBFO may be expressed on the basis of three-dimensional coordinate system. As illustrated in FIG. 4, the three-dimensional coordinate system is composed of an X-axis, a Y-axis, and a Z-axis. Any coordinates in the coordinate system are expressed as (X,Y,Z). Coordinates (x, y, z) in the coordinate system represent x, y, and z in the Chemical Formula 1. A sum of x, y, and z in the Chemical Formula 1 is 1, and any of x, y, and z is a positive real number. Accordingly, the coordinates (x, y, z) are located inside of a triangle drawn by a dotted line in a plane expressed by X+Y+Z=1. That is, the coordinates (x, y, z) are located inside of a triangle which vertexes are coordinates (1, 0, 0), coordinates (1, 1, 0), and coordinates (0, 0, 1). The triangle is shown in FIG. 5 as trigonal coordinates. In FIG. 5, coordinates A are (0.300, 0.100, 0.600). Coordinates B are (0.450, 0.250, 0.300). Coordinates C are (0.200, 0.500, 0.300). Coordinates D are (0.100, 0.300, 0.600). Coordinates E are (0.400, 0.200, 0.400). Coordinates F are (0.200, 0.400, 0.400). All of the coordinates A, the coordinates B, the coordinates C, the coordinates D, the coordinates E, and the coordinates F are located within a plane expressed by X+Y+Z=1. The coordinates (x,y,z) representing x, y, and z in Chemical Formula 1 may be located within a square which vertexes are the coordinates A, the coordinates B, the coordinates C, and the coordinates D. In a case where the coordinates (x,y,z) are within the square ABCD, the composition of xBKT-yBMT-zBFO is likely to have MPB, and piezoelectric properties and ferroelectricity of the piezoelectric thin film 3 are likely to be improved. For the same reason, the coordinates (x,y,z) may be located in a square which vertexes are the coordinates A, the coordinates E, the coordinates F, and the coordinates D. x may be equal to y. In a case where x is equal to y, the coordinates (x,y,z) are located on a straight line passing through coordinates (0.500, 0.500, 0) and coordinates (0, 0, 1). In a case where x is equal to y, the composition of xBKT-yBMT-zBFO is likely to have MPB, and piezoelectric properties and ferroelectricity of the piezoelectric thin film 3 are likely to be improved.

x may be from 0.100 to 0.450, y may be from 0.100 to 0.500, and z may be from 0.300 to 0.600. x may be from 0.100 to 0.400, y may be from 0.100 to 0.400, and z may be from 0.400 to 0.600. x may be from 0.150 to 0.350, y may be from 0.150 to 0.350, and z may be from 0.300 to 0.600. x may be from 0.250 to 0.300, y may be 0.250 to 0.300, and z may be 0.400 to 0.600. In a case where x, y, and z are within the above-described ranges, and x+y+z is 1, the composition of xBKT-yBMT-zBFO is likely to have MPB, and piezoelectric properties and ferroelectricity of the piezoelectric thin film 3 are likely to be improved.

A thickness of the piezoelectric thin film 3 may be, for example, from 10 nm to 10 μm, from 0.3 μm to 10 μm, from 0.3 μm to 5 μm, from 0.5 μm to 5 μm, from 0.3 μm to 3 μm, or from 0.5 μm to 3 μm. The resonance frequency of the piezoelectric thin film 3 increases in accordance with a decrease in the thickness of the piezoelectric thin film 3. An area of the piezoelectric thin film 3 may be, for example, 1 μm² to 500 μm². An area of each of the single crystal substrate 1, the first intermediate layer 5, the first electrode layer 2, the second intermediate layer 6, and the second electrode layer 4 may be the same as the area of the piezoelectric thin film 3.

The composition of the piezoelectric thin film 3 may be analyzed, for example, by a fluorescent X-ray analysis method (XRF method) or an inductively coupled plasma (ICP) emission spectrometry.

The crystal structure and the crystal orientation property of the piezoelectric thin film 3 may be specified by an X-ray diffraction (XRD) method.

The piezoelectric thin film 3 may be formed, for example, by the following method.

As a raw material of the piezoelectric thin film 3, a target having a similar composition as in the piezoelectric thin film 3 may be used. A method of preparing the target is as follows.

As starting raw materials, for example, a powder of each of bismuth oxide, potassium carbonate, titanium oxide, an oxide of the element M, and iron oxide may be used. The oxide of the element M may be at least any one between magnesium oxide and nickel oxide. As the starting raw materials, materials such as carbonate and oxalate that become oxides through sintering may be used instead of the oxides. After sufficiently drying the starting raw materials at a temperature of 100° C. or higher, the starting raw materials are weighed so that the numbers of moles of Bi, K, Ti, the element M, and Fe are within the ranges defined by the Chemical Formula 1. In a vapor deposition method to be described later, Bi and K in the target are more likely to volatilize in comparison to other elements. Accordingly, a molar ratio of Bi in the target may be adjusted to a value higher than a molar ratio of Bi in the piezoelectric thin film 3. A molar ratio of K in the target may be adjusted to a value higher than a molar ratio of K in the piezoelectric thin film 3.

The weighed starting raw materials are sufficiently mixed in an organic solvent or water. A mixing time may be from 5 hours to 20 hours. A mean for the mixing may be a ball mill. After the mixed starting raw materials are sufficiently dried, the starting raw materials are molded by a press machine. A calcined product is obtained by calcining the molded starting raw materials. A calcination temperature may be from 750° C. to 900° C. A calcination time may be from 1 hour to 3 hours. The calcined product is pulverized in an organic solvent or water. A pulverization time may be from 5 hours to 30 hours. A mean for the pulverization may be a ball mill. After drying the pulverized calcined product, the calcined product to which a binder solution is added is granulated to obtain a powder of the calcined product. A block-shaped compact is obtained by press molding the powder of the calcined product.

The block-shaped compact is heated to evaporate the binder in the compact. A heating temperature may be from 400° C. to 800° C. A heating time may be from 2 hours to 4 hours. Next, the compact is sintered. A sintering temperature may be from 800° C. to 1100° C. A sintering time may be from 2 hours to 4 hours. A temperature-rising rate and a temperature-lowering rate of the compact during the sintering process may be, for example, from 50° C./hour to 300° C./hour.

The target is obtained through the above-described process. An average grain size of a crystal grain of the metal oxide contained in the target may be, for example, from 1 μm to 20 μm.

The piezoelectric thin film 3 may be formed by a vapor deposition method using the target. In the vapor deposition method, elements constituting the target are evaporated in a vacuum atmosphere. When the evaporated elements adhere to and are deposited on a surface of any one of the second intermediate layer 6, the first electrode layer 2, and single crystal substrate 1, the piezoelectric thin film 3 grows. The vapor deposition method may be, for example, a sputtering method, an electron beam deposition method, a chemical vapor deposition method, or a pulsed-laser deposition method. In the following description, the pulsed-laser deposition method is noted as a PLD method. By using the vapor deposition methods, it is possible to form the piezoelectric thin film 3 that is dense in an atomic level, and segregation of elements in the piezoelectric thin film 3 is suppressed. An excitation source is different depending on the kind of the vapor deposition method. An excitation source of the sputtering method is Ar plasma. An excitation source of the electron beam deposition method is an electron beam. An excitation source of the PLD method is laser light (for example, an excimer laser). When a target is irradiated with the excitation sources, elements constituting the target evaporate.

Among the above-described vapor deposition methods, the PLD method is relatively excellent from the following viewpoints. Respective elements constituting a target can be instantly and evenly made into plasma by a pulsed-laser in the PLD method. Accordingly, the piezoelectric thin film 3 having a composition that is approximately the same as that of the target is likely to be formed. In addition, the thickness of the piezoelectric thin film 3 can be easily controlled by changing the number of shots of the laser pulse in the PLD method.

The piezoelectric thin film 3 may be an epitaxial film. That is, the piezoelectric thin film 3 may be formed by epitaxial growth. The piezoelectric thin film 3 excellent in crystal orientation property is likely to be formed by the epitaxial growth. In a case where the piezoelectric thin film 3 is formed by the PLD method, the piezoelectric thin film 3 is likely to be formed by the epitaxial growth.

In the PLD method, the piezoelectric thin film 3 may be formed while heating the single crystal substrate 1 and the first electrode layer 2 in a vacuum chamber. A temperature (a film formation temperature) of the single crystal substrate 1 and the first electrode layer 2 may be, for example, from 300° C. to 800° C., from 500° C. to 700° C., or from 500° C. to 600° C. As the film formation temperature is higher, cleanness of a surface of the single crystal substrate 1 or the first electrode layer 2 is further improved, crystallinity of the piezoelectric thin film 3 further increases, and the degree of orientation of the crystal planes is more likely to increase. In a case where the film formation temperature is excessively high, Bi or K is likely to desorb from the piezoelectric thin film 3, and it is difficult to control the composition of the piezoelectric thin film 3.

In the PLD method, a partial pressure of oxygen inside the vacuum chamber may be, for example, more than 10 mTorr and less than 400 mTorr, from 15 mTorr to 300 mTorr, or from 20 mTorr to 200 mTorr. In other words, the partial pressure of oxygen inside the vacuum chamber may be, for example, more than 1 Pa and less than 53 Pa, from 2 Pa to 40 Pa, or from 3 Pa to 30 Pa. When the partial pressure of oxygen is maintained within the above-described range, Bi, K, Ti, the element M, and Fe deposited above the single crystal substrate 1 are likely to be sufficiently oxidized. In a case where the partial pressure of oxygen is excessively high, a growth rate of the piezoelectric thin film 3 is likely to decrease, and a degree of orientation of a crystal plane of the piezoelectric thin film 3 is likely to decrease.

Examples of parameters other than the above parameters controlled in the PLD method include a laser oscillation frequency, a distance between the substrate and a target, and the like. The crystal structure and the crystal orientation property of the piezoelectric thin film 3 are likely to be controlled by controlling the parameters. For example, in a case where the laser oscillation frequency is 10 Hz or less, the degree of orientation of the crystal plane of the piezoelectric thin film 3 is likely to increase.

After the piezoelectric thin film 3 is grown, an annealing treatment (heating treatment) for the piezoelectric thin film 3 may be performed. A temperature (annealing temperature) of the piezoelectric thin film 3 in the annealing treatment may be, for example, from 300° C. to 1000° C., from 600° C. to 1000° C., or from 850° C. to 1000° C. The piezoelectric properties of the piezoelectric thin film 3 tend to be further improved by the annealing treatment for the piezoelectric thin film 3. Particularly, the piezoelectric properties of the piezoelectric thin film 3 are likely to be improved by the annealing treatment at from 850° C. to 1000° C. However, the annealing treatment is not essential.

The single crystal substrate 1 may be, for example, a substrate consisting of a single crystal of Si, or a substrate consisting of a single crystal of a compound semiconductor such as GaAs. The single crystal substrate 1 may be a substrate consisting of a single crystal of an oxide such as MgO or a perovskite type oxide (for example, SrTiO₃). A thickness of the single crystal substrate 1 may be, for example, from 10 μm to 1000 μm. In a case where the single crystal substrate 1 has electrical conductivity, since the single crystal substrate 1 functions as an electrode, the first electrode layer 2 does not have to exist. That is, the single crystal substrate 1 having electrical conductivity may be, for example, a single crystal of niobium-doped SrTiO₃. A silicon-on-insulator (SOI) substrate may be used instead of the single crystal substrate 1.

A crystal orientation of the single crystal substrate 1 may be equal to a normal direction of a surface of the single crystal substrate 1. That is, the surface of the single crystal substrate 1 may be parallel to a crystal plane of the single crystal substrate 1. The single crystal substrate 1 may be a uniaxially oriented substrate. For example, one crystal plane selected from the group consisting of a (100) plane, a (001) plane, a (110) plane, a (101) plane, and a (111) plane may be parallel to the surface of the single crystal substrate 1. In a case where the (100) plane of the single crystal substrate 1 (for example, Si) is parallel to the surface of the single crystal substrate 1, the (001) plane of the perovskite type oxide in the piezoelectric thin film 3 is likely to be oriented in the thickness direction dn of the piezoelectric thin film 3.

As described above, the first intermediate layer 5 may be disposed between the single crystal substrate 1 and the first electrode layer 2. For example, the first intermediate layer 5 may contain at least one kind selected from the group consisting of titanium (Ti), chromium (Cr), titanium oxide (TiO₂), silicon oxide (SiO₂), and zirconium oxide (ZrO₂). When the first intermediate layer 5 is interposed, the first electrode layer 2 is likely to come into close contact with the single crystal substrate 1. The first intermediate layer 5 may be crystalline. A crystal plane of the first intermediate layer 5 may be oriented in a normal direction of the surface of the single crystal substrate 1. Both the crystal plane of the single crystal substrate 1 and the crystal plane of the first intermediate layer 5 may be oriented in the normal direction of the surface of the single crystal substrate 1. A method of forming the first intermediate layer 5 may be a sputtering method, a vacuum deposition method, a printing method, a spin coating method, or a sol-gel method.

The first intermediate layer 5 may contain ZrO₂ and an oxide of a rare-earth element. When the first intermediate layer 5 contains ZrO₂ and an oxide of a rare-earth element, the first electrode layer 2 consisting of a crystal of platinum is likely to be formed on a surface of the first intermediate layer 5, and a (002) plane of the crystal of platinum is likely to be oriented in the normal direction DN of the surface of the first electrode layer 2, and a (200) plane of the crystal of platinum is likely to be oriented in an in-plane direction of the surface of the first electrode layer 2. The rare-earth element may be at least one kind selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). The first intermediate layer 5 may consist of yttria-stabilized zirconia (Y₂O₃—added ZrO₂). When the first intermediate layer 5 consists of the yttria-stabilized zirconia, the first electrode layer 2 consisting of the crystal of platinum is likely to be formed on a surface of the first intermediate layer 5, and the (002) plane of the crystal of platinum is likely to be oriented in the normal direction DN of the surface of the first electrode layer 2, the (200) plane of the crystal of platinum is likely to be oriented in the in-plane direction of the surface of the first electrode layer 2. For the same reason, the first intermediate layer 5 may include a first layer consisting of ZrO₂ and a second layer consisting of Y₂O₃. The first layer may be stacked directly on the surface of the single crystal substrate 1, the second layer may be stacked directly on a surface of the first layer, and the first electrode layer 2 may be stacked directly on a surface of the second layer.

For example, the first electrode layer 2 may consist of at least one kind of metal selected from the group consisting of Pt (platinum), Pd (palladium), Rh (rhodium), Au (gold), Ru (ruthenium), Ir (iridium), Mo (molybdenum), Ti (titanium), Ta (tantalum), and Ni (nickel). For example, the first electrode layer 2 may consist of a conductive metal oxide such as strontium ruthenate (SrRuO₃), lanthanum nickelate (LaNiO₃), and lanthanum strontium cobaltate ((La, Sr)CoO₃). The first electrode layer 2 may be crystalline. A crystal plane of the first electrode layer 2 may be oriented in the normal direction of the surface of the single crystal substrate 1. The crystal plane of the first electrode layer 2 may be approximately parallel to the surface of the single crystal substrate 1. Both the crystal plane of the single crystal substrate 1 and the crystal plane of the first electrode layer 2 may be oriented in the normal direction of the surface of the single crystal substrate 1. The crystal plane of the first electrode layer 2 may be approximately parallel to the crystal plane of the perovskite type oxide that is oriented in the piezoelectric thin film 3. A thickness of the first electrode layer 2 may be, for example, from 1 nm to 1.0 μm. A method of forming the first electrode layer 2 may be a sputtering method, a vacuum deposition method, a printing method, a spin coating method, or a sol-gel method. In a case of the printing method, the spin coating method, or the sol-gel method, a heating treatment (annealing) for the first electrode layer 2 may be performed in order to increase crystallinity of the first electrode layer 2.

The first electrode layer 2 may contain a crystal of platinum. The first electrode layer 2 may consist only of the crystal of platinum. The crystal of platinum is a cubic crystal having a face-centered cubic lattice structure. A (002) plane of the crystal of platinum may be oriented in the normal direction DN of the surface of the first electrode layer 2, and a (200) plane of the crystal of platinum may be oriented in the in-plane direction of the surface of the first electrode layer 2. In other words, the (002) plane of the crystal of platinum may be approximately parallel to the surface of the first electrode layer 2, and the (200) plane of the crystal of platinum may be approximately orthogonal to the surface of the first electrode layer 2. In a case where the (002) plane and the (200) plane of the crystal of platinum constituting the first electrode layer 2 have the above-described orientations, the piezoelectric thin film 3 is likely to epitaxially grow on the surface of the first electrode layer 2, and a lattice stress caused by lattice mismatching between the first electrode layer 2 and the piezoelectric thin film 3 is likely to act on the piezoelectric thin film 3. As a result, the piezoelectric thin film 3 is likely to contain a tetragonal crystal of the perovskite type oxide, a (001) plane of the tetragonal crystal is likely to be preferentially oriented in the thickness direction dn of the piezoelectric thin film 3, and the piezoelectric thin-film element 10 is likely to have a high resonance frequency, a large d_{33.f}, and a large performance index P.

The second intermediate layer 6 may be disposed between the first electrode layer 2 and the piezoelectric thin film 3. The second intermediate layer 6 may contain, for example, at least one kind selected from the group consisting of SrRuO₃, LaNiO₃, and (La, Sr)CoO₃. When the second intermediate layer 6 is interposed, the piezoelectric thin film 3 is likely to come into close contact with the first electrode layer 2. The second intermediate layer 6 may be crystalline. In a case where the second intermediate layer 6 includes at least one between SrRuO₃ and LaNiO₃, a lattice stress caused by lattice mismatching between the second intermediate layer 6 and the piezoelectric thin film 3 is likely to act on the piezoelectric thin film 3. As a result, the piezoelectric thin film 3 is likely to contain a tetragonal crystal of a perovskite type oxide, and the (001) plane of the tetragonal crystal is likely to be preferentially oriented in the thickness direction dn of the piezoelectric thin film 3, and the piezoelectric thin-film element 10 is likely to have a high resonance frequency, a large d_{33.f}, and a large performance index P. A crystal plane of the second intermediate layer 6 may be oriented in the normal direction DN of the surface of the first electrode layer 2. Both the crystal plane of the single crystal substrate 1 and the crystal plane of the second intermediate layer 6 may be oriented in the normal direction DN of the surface of the first electrode layer 2. A method of forming the second intermediate layer 6 may be a sputtering method, a vacuum deposition method, a printing method, a spin coating method, or a sol-gel method.

The second electrode layer 4 may consist of, for example, at least one metal selected from the group consisting of Pt, Pd, Rh, Au, Ru, Ir, Mo, Ti, Ta, and Ni. The second electrode layer 4 may consist of, for example, at least one conductive metal oxide selected from the group consisting of LaNiO₃, SrRuO₃, and (La, Sr)CoO₃. The second electrode layer 4 may be crystalline. A crystal plane of the second electrode layer 4 may be oriented in the thickness direction dn of the piezoelectric thin film 3. The crystal plane of the second electrode layer 4 may be approximately parallel to a surface of the piezoelectric thin film 3. The crystal plane of the second electrode layer 4 may be approximately parallel to the (001) plane that is oriented in the piezoelectric thin film 3. A thickness of the second electrode layer 4 may be, for example, from 1 nm to 1.0 μm. A method of forming the second electrode layer 4 may be a sputtering method, a vacuum deposition method, a printing method, a spin coating method, or a sol-gel method. In a case of the printing method, the spin coating method, or the sol-gel method, a heating treatment (annealing) for the second electrode layer 4 may be performed in order to increase crystallinity of the second electrode layer 4.

A third intermediate layer may be disposed between the piezoelectric thin film 3 and the second electrode layer 4. When the third intermediate layer is interposed, the second electrode layer 4 is likely to come into close contact with the piezoelectric thin film 3. Due to the lattice mismatching between the crystalline third intermediate layer and the piezoelectric thin film 3, the above-described lattice stress is likely to act on the piezoelectric thin film 3. As a result, the piezoelectric thin film 3 is likely to contain the tetragonal crystal of the perovskite type oxide, the (001) plane of the tetragonal crystal is likely to be preferentially oriented in the thickness direction dn of the piezoelectric thin film 3, and the piezoelectric thin-film element 10 is likely to have a high resonance frequency, a large d_{33.f}, and a large performance index P. A composition, a crystal structure, and a formation method of the third intermediate layer may be the same as in the second intermediate layer 6.

At least a part or the entirety of the surface of the piezoelectric thin-film element 10 may be coated with a protective film. When the piezoelectric thin-film element 10 is coated with the protective film, for example, humidity resistance of the piezoelectric thin-film element 10 is improved.

An application of the piezoelectric thin-film element according to this embodiment is various. For example, the piezoelectric thin-film element may be used in a piezoelectric transducer and a piezoelectric sensor. That is, the piezoelectric transducer (for example, an ultrasonic transducer) according to this embodiment may include the above-described piezoelectric thin-film element. The piezoelectric transducer may be, for example, an ultrasonic transducer such as an ultrasonic sensor. For example, the piezoelectric thin-film element may be a harvester (vibration oscillation element). As described above, according to the piezoelectric thin-film element according to this embodiment, the performance index P is from 10% to 80.1%, the resonance frequency of thickness longitudinal vibration of the piezoelectric thin film is relatively high, and a dielectric loss at the high resonance frequency is suppressed. For example, the resonance frequency of thickness longitudinal vibration of the piezoelectric thin film is from 0.10 GHz to 2 GHZ. Therefore, the piezoelectric thin-film element according to this embodiment is suitable for the ultrasonic transducer. The piezoelectric thin-film element may be a piezoelectric actuator. The piezoelectric actuator may be used in a head assembly, a head stack assembly, or a hard disk driver. The piezoelectric actuator may be used in a printer head or an inkjet printer device. The piezoelectric actuator may be a piezoelectric switch. The piezoelectric actuator may be used in haptics. That is, the piezoelectric actuator may be used in various devices where a feedback due to cutaneous sensation (haptic sense) is required. For example, the devices that require the feedback due to cutaneous sensation may be wearable devices, touch pads, displays, or game controllers. The piezoelectric thin-film element may be a piezoelectric sensor. For example, the piezoelectric sensor may be a piezoelectric microphone, a gyro sensor, a pressure sensor, a pulse wave sensor, a blood glucose level sensor, or a shock sensor. The piezoelectric thin-film element may be a BAW filter, an oscillator, or an acoustic multilayer film. A micro electro mechanical system (MEMS) according to this embodiment includes the above-described piezoelectric thin-film element. That is, the piezoelectric thin-film element may be a part or the entirety of the micro electro mechanical system. For example, the piezoelectric thin-film element may be a part or the entirety of a piezoelectric micromachined ultrasonic transducer (PMUT). For example, a product to which the piezoelectric micromachined ultrasonic transducer is applied may be a biometric authentication sensor (fingerprint authentication sensor, a blood vessel authentication sensor, or the like), a medical/healthcare sensor (blood pressure meter, a blood vessel imaging sensor, or the like), or a time of flight (ToF) sensor. In a case where the resonance frequency is approximately 0.1 GHz, attenuation in the piezoelectric thin-film element (for example, the blood glucose level sensor) is likely to be suppressed.

FIG. 6 illustrates a schematic cross-section of an ultrasonic transducer 10a that is an example of the piezoelectric thin-film element. A cross-section of the ultrasonic transducer 10a is approximately parallel to the thickness direction dn of the piezoelectric thin film 3. The ultrasonic transducer 10a may include substrates 1a and 1b, the first electrode layer 2 provided on the substrates 1a and 1b, the piezoelectric thin film 3 stacked on the first electrode layer 2, and the second electrode layer 4 stacked on the piezoelectric thin film 3. An acoustic cavity 1c may be provided under the piezoelectric thin film 3. An ultrasonic signal is transmitted or received by bending or vibration of the piezoelectric thin film 3. A first intermediate layer may be interposed between the substrates 1a and 1b and the first electrode layer 2. A second intermediate layer may be interposed between the first electrode layer 2 and the piezoelectric thin film 3. The second intermediate layer may be interposed between the piezoelectric thin film 3 and the second electrode layer 4.

### EXAMPLES

Hereinafter, the present invention will be described in more detail with reference to examples, but the present invention is not limited to the examples.

### Example 1

A single crystal substrate (Si wafer) consisting of Si was used in preparation of a piezoelectric thin-film element of Example 1. A (100) plane of Si was parallel to a surface of the single crystal substrate. A diameter o of the single crystal substrate was 3 inches. A thickness of the single crystal substrate was 400 μm.

A crystalline first intermediate layer consisting of ZrO₂ and Y₂O₃ was formed on the entirety of the surface of the single crystal substrate in a vacuum chamber.” The first intermediate layer was formed by a sputtering method. A thickness of the first intermediate layer was 30 nm.

A first electrode layer consisting of a crystal of Pt was formed on the entirety of a surface of the first intermediate layer in the vacuum chamber. The first electrode layer was formed by a sputtering method. A thickness of the first electrode layer was 200 nm. A temperature (film formation temperature) of the single crystal substrate during a process of forming the first electrode layer was kept at 500° C.

A plurality of rectangular stacked bodies including the single crystal substrate, the first intermediate layer, and the first electrode layer were prepared by dicing a stacked body prepared by the above-described method. That is, a plurality of stacked bodies were prepared as samples for analysis and measurement to be described later. Dimensions of each stacked body in a direction orthogonal to a stacking direction of the each stacked body were adjusted to 10 mm×10 mm. That is, dimensions of the piezoelectric thin film in a direction orthogonal to a thickness direction of the piezoelectric thin film were adjusted to 10 mm×10 mm.

An X-ray diffraction (XRD) pattern of the first electrode layer was measured by out-of-plane measurement on a surface of the first electrode layer. Another XRD pattern of the first electrode layer was measured by in-plane measurement on the surface of the first electrode layer. In the measurements of the XRD patterns, an X-ray diffraction device (SmartLab) manufactured by Rigaku Corporation was used. Measurement conditions were set so that each peak intensity in the XRD patterns becomes higher than a background intensity by at least three digits or more. A peak of diffracted X-ray of a (002) plane of a crystal of Pt was detected by the out-of-plane measurement. That is, the (002) plane of the crystal of Pt was oriented in a normal direction of the surface of the first electrode layer. A peak of a diffracted X-ray of a (200) plane of the crystal of pt was detected by the in-plane measurement. That is, the (200) plane of the crystal of Pt was oriented in an in-plane direction of the surface of the first electrode layer.

A second intermediate layer consisting of crystalline LaNiO₃ was formed on the entirety of the surface of the first electrode layer in the vacuum chamber. The second intermediate layer was formed by a sputtering method. A thickness of the second intermediate layer was 50 nm.

A piezoelectric thin film was formed on the entirety of a surface of the second intermediate layer in the vacuum chamber. The piezoelectric thin film was formed by a PLD method. A thickness T of the piezoelectric thin film of Example 1 was adjusted to a value shown in the following Table 1. A temperature (film formation temperature) of the single crystal substrate during a process of forming the piezoelectric thin film was kept at 500° C. A partial pressure of oxygen in the vacuum chamber during the process of forming the piezoelectric thin film was kept at 10 Pa. As a raw material of the piezoelectric thin film, a target (a sintered body of a raw material powder) was used. When preparing the target, a blending ratio of raw material powders (bismuth oxide, potassium carbonate, titanium oxide, magnesium oxide, and iron oxide) was adjusted in correspondence with a desired composition of the piezoelectric thin film. The desired composition of the piezoelectric thin film of Example 1 is expressed by the chemical formula in the following Table 1. “BKT” in the following Table 1 represents (Bi_{0.5}K_{0.5})TiO₃. “BMT” in the following Table 1 represents Bi(Mg_{0.5}Ti_{0.5})O₃. “BFO” in the following Table 1 represents BiFeO₃.

A stacked body including the single crystal substrate, the first intermediate layer stacked on the single crystal substrate, the first electrode layer stacked on the first intermediate layer, the second intermediate layer stacked on the first electrode layer, and the piezoelectric thin film stacked on the second intermediate layer was prepared by the above-described method.

### <Analysis of Composition>

The composition of the piezoelectric thin film was analyzed by a fluorescent X-ray analysis method (XRF method). In the analysis, a device PW2404 manufactured by Philips Japan, Ltd. was used. The composition of the piezoelectric thin film of Example 1, which was specified by analysis, matched the chemical formula in the following Table 1.

### <Analysis of Crystal Structure>

An XRD pattern of the piezoelectric thin film was measured by out-of-plane measurement on a surface of the piezoelectric thin film. Another XRD pattern of the piezoelectric thin film was measured by in-plane measurement on the surface of the piezoelectric thin film. A measurement device and measurement conditions for the XRD patterns were similar as described above.

The XRD patterns of the piezoelectric thin film represented that the piezoelectric thin film is composed of a perovskite type oxide. A peak of a diffracted X-ray of a (001) plane of the perovskite type oxide was detected by the out-of-plane measurement. That is, the (001) plane of the perovskite type oxide was oriented in a thickness direction of the piezoelectric thin film (a normal direction of the surface of the piezoelectric thin film).

A lattice constant c of the perovskite type oxide in the thickness direction of the piezoelectric thin film (the normal direction of the surface of the piezoelectric thin film) was obtained by the out-of-plane measurement. The lattice constant c can also be referred to as an interval of a crystal plane in the thickness direction of the piezoelectric thin film. A lattice constant a of the perovskite type oxide in a direction parallel to the surface of the piezoelectric thin film was obtained by the in-plane measurement. The lattice constant a can also be referred to as an interval of a crystal plane orthogonal to the surface of the piezoelectric thin film. a was smaller than c. That is, the perovskite type oxide contained in the piezoelectric thin film was tetragonal crystal. c/a in Example 1 is shown in the following Table 1.

### <Measurement of Young's Modulus Y>

A Young's modulus Y of the piezoelectric thin film was measured by a nanoindentation method. The above-described stacked body was used as a measurement sample. Measurement of the Young's modulus by the nanoindentation method is based on International Standard ISO 14577. In the measurement of the Young's modulus Y, a nano-indenter (device name: TI 950 TriboIndenter) manufactured by Hysitron Inc. was used. The Young's modulus Y in Example 1 is shown in the following Table 1.

<Measurement of Piezoelectric Strain Constant d_{33.f}>

A piezoelectric strain constant d_{33.f} of the piezoelectric thin film was specified on the basis of the following method.

A sample for measurement of d_{33.f} was prepared from the above-described stacked body. A plurality of dot-shaped electrodes arranged in a lattice pattern were formed on the surface of the piezoelectric thin film. The dot-shaped electrodes consisted of silver. A diameter ϕ of the each dot-shaped electrode was 100 μm. An interval of the dot-shaped electrodes was 300 μm. An electric field (voltage) was applied between the each dot-shaped electrode and the first electrode layer, and an amount of displacement of each of the piezoelectric thin film and the single crystal substrate in the thickness direction of the piezoelectric thin film in accordance with the application of the electric field was measured. An intensity of the electric field was 10 V/μm. The amount of displacement of each of the piezoelectric thin film and the single crystal substrate was measured by a double beam type laser Doppler vibration meter. The stacked body including the piezoelectric thin film and the single crystal substrate was disposed between a first laser beam and a second laser beam. The first laser beam and the second laser beam were located on the same straight line and propagation directions of the first laser beam and the second laser beam faced each other. The propagation direction of each of the first laser beam and the second laser beam was parallel to the thickness direction of the piezoelectric thin film. The surface of the piezoelectric thin film was irradiated with the first laser beam and the surface of the single crystal substrate (that is, a rear surface of the stacked body) was irradiated with the second laser beam. A difference between the amount of displacement measured by the first laser beam and the amount of displacement measured by the second laser beam was simultaneously measured to exclude an influence due to the single crystal substrate, and an amount of pure displacement in a thickness longitudinal direction of the piezoelectric thin film is obtained. d_{33.f} was calculated from the amount of change in the thickness T of the piezoelectric thin film and electric field intensity dependency thereof. d_{33.f} of Example 1 is shown in the following Table 1.

### <Measurement of Relative Permittivity ε₃₃ and Dielectric Loss>

An electrostatic capacitance C and a dielectric loss (tanδ) were measured by using a similar sample as in the measurement of d_{33.f}. Details of measurement of the electrostatic capacitance C and tan δ were as follows.

Measurement device: LCR meter (E4980A) manufactured by Agilent Technologies, Inc.
Frequency: 10 KHz
Electric field: 1 V/μm

Relative permittivity Er was calculated from a measurement value of an electrostatic capacitance C on the basis of the following Mathematical Formula A. ε₀ in the Mathematical Formula A is permittivity of vacuum (8.854×10⁻¹² Fm⁻¹). S in the Mathematical Formula A is an area of the surface of the piezoelectric thin film. S can also be referred to as a total area of the dot-shaped electrodes (silver electrodes) stacked on the surface of the piezoelectric thin film. T in the Mathematical Formula A is a thickness of the piezoelectric thin film.

$$\\ \begin{matrix}C = {ε}_{0} \times {ε}_{r} \times ( S / T ) & ( A )\end{matrix}$$

The relative permittivity ε specified by the above-described method was regarded as ε₃₃. ε₃₃ and tanδ in Example 1 are shown in the following Table 1.

The following processes were further carried out by using the stacked body (that is, a stacked body without the dot-shaped electrode consisting of silver) including the single crystal substrate, the first intermediate layer, the first electrode layer, the second intermediate layer, and the piezoelectric thin film.

A third intermediate layer consisting of crystalline LaNiO₃ was formed on the entirety of the surface of the piezoelectric thin film in the vacuum chamber. The third intermediate layer was formed by a sputtering method. A thickness of the third intermediate layer was 50 nm.

A second electrode layer consisting of Pt was formed on the entirety of a surface of the third intermediate layer in the vacuum chamber. The second electrode layer was formed by a sputtering method. A temperature of the single crystal substrate during a process of forming the second electrode layer was kept at 500° C. A thickness of the second electrode layer was 200 nm.

Through the above-described processes, a stacked body including the single crystal substrate, the first intermediate layer stacked on the single crystal substrate, the first electrode layer stacked on the first intermediate layer, the second intermediate layer stacked on the first electrode layer, the piezoelectric thin film stacked on the second intermediate layer, the third intermediate layer stacked on the piezoelectric thin film, and the second electrode layer stacked on the third intermediate layer was prepared. Patterning of the stacked structure on the single crystal substrate was performed by the subsequent photolithography. After the patterning, the stacked body was cut out through dicing.

A rectangular piezoelectric thin-film element of Example 1 was obtained by the above-described processes. The piezoelectric thin-film element included the single crystal substrate, the first intermediate layer stacked on the single crystal substrate, the first electrode layer stacked on the first intermediate layer, the second intermediate layer stacked on the first electrode layer, the piezoelectric thin film stacked on the second intermediate layer, the third intermediate layer stacked on the piezoelectric thin film, and the second electrode layer stacked on the third intermediate layer.

<Measurement of Piezoelectric Stress Constant −e_{31,f}>

A rectangular sample (cantilever) was prepared as the piezoelectric thin-film element in order to measure a piezoelectric stress constant −e_{31,f} of the piezoelectric thin film. Dimensions of the sample were 2 mm (width)×10 mm (length). Dimensions of each of the electrode layers were 1.6 mm (width)×6 mm (length). The sample was the same as the piezoelectric thin-film element of Example 1 except for the dimensions. A self-made evaluation system was used for the measurement. One end of the sample was fixed, and the other end of the sample was a free end. An amount of displacement of the free end of the sample was measured with a laser while applying a voltage to the piezoelectric thin film in the sample. Then, the piezoelectric constant −e_{31,f} was calculated from the following Mathematical Formula B. Note that, Es in the Mathematical Formula B is a Young's modulus of the single crystal substrate. hₛ is a thickness of the single crystal substrate. L is a length of the sample (cantilever). Vs is a Poisson's ratio of the single crystal substrate. δₒᵤₜ is an output displacement based on the amount of displacement measured. Vᵢₙ is a voltage applied to the piezoelectric thin film. A frequency of an AC electric field (AC voltage) in the measurement of the piezoelectric constant −e_{31,f} was 100 Hz. A maximum value of the voltage applied to the piezoelectric thin film was 50 V. A unit of −e_{31,f} is C/m². −e_{31,f} in Example 1 is shown in the following Table 2.

$$\\ \begin{matrix}[ Mathematical Formula 1 ] & \\ - {e}_{31 , f} = \frac{{E}_{s} {h}_{s}^{{}_{} 2}}{3 {L}^{{}_{} 2} ( 1 - {v}_{s} )} \cdot \frac{{δ}_{out}}{{V}_{in}} & ( B )\end{matrix}$$

A performance index P (that is, (d_{33.f})²×Y/ε) in Example 1 is shown in the following Table 1. −e_{31,f}/e₃₃ in Example 1 is shown in the following Table 2. e₃₃ was calculated by the product (d_{33.f}×Y) of measurement values of d_{33.f} and Y.

<Measurement of Resonance Frequency fᵣ>

A stacked body including an SOI substrate, the first intermediate layer, the first electrode layer, the second intermediate layer, the piezoelectric thin film, the third intermediate layer, and the second electrode layer was prepared by a similar method as in Example 1 except that the SOI substrate was used instead of the Si wafer. The SOI substrate included a support base material consisting of Si, a BOX layer (an insulation layer consisting of SiO₂) stacked on the support base material, and a silicon layer (layer consisting of a single crystal of Si) stacked on the BOX layer. The first intermediate layer, the first electrode layer, the second intermediate layer, the piezoelectric thin film, the third intermediate layer, and the second electrode layer were sequentially stacked on the silicon layer of the SOI substrate. After preparing the stacked body, the support base material and the BOX layer constituting the SOI substrate were etched to expose the silicon layer partially. A sample (piezoelectric thin-film element) having a membrane structure of Example 1 was prepared by the above-described method. Dimensions of the sample (an area of the piezoelectric thin film) were adjusted to 20 mm×20 mm. A resonance frequency fᵣ of the sample was measured. The resonance frequency fᵣ is a frequency when an impedance of a resonance circuit using the sample is the smallest. Details of measurement of the resonance frequency fᵣ were as follows. The resonance frequency fᵣ in Example 1 is shown in the following Table 1.
Measurement device: network analyzer (N5244A) manufactured by Agilent Technologies, Inc.
Probe: GS 500 μm (ACP40-W-GS-500, manufactured by Cascade Microtech, Inc.)
Power: −10 dBm
Measurement pitch: 0.25 MHz
Electrode area: 200×200 μm²
S11 measurement (reflection measurement)

### Examples 2 to 9 and Comparative Examples 1 to 5

A piezoelectric thin film of each of Examples 2 to 9 and Comparative Examples 1 to 5 was formed by using a target having a composition shown in the following Table 1. “PZT” in the following Table 1 represents Pb(Zr_{0.5}Ti_{0.5})O₃. The thickness T of each of the piezoelectric thin films of Examples 2 to 9 and Comparative Examples 1 to 5 was adjusted to a value shown in the following Table 1. The piezoelectric thin-film element of each of Examples 2 to 9 and Comparative Examples 1 to 5 was prepared by a similar method as in Example 1 except for the above-described items.

XRD patterns of the first electrode layer of each of Examples 2 to 9 and Comparative Examples 1 to 5 were measured by a similar method as in Example 1. Even in any case of Examples 2 to 9 and Comparative Examples 1 to 5, a (002) plane of a crystal of Pt constituting the first electrode layer was oriented in a normal direction of a surface of the first electrode layer, and a (200) plane of the crystal of Pt was oriented in an in-plane direction of a surface of the first electrode layer.

A composition of the piezoelectric thin film of each of Examples 2 to 9 and Comparative Examples 1 to 5 was analyzed by a similar method as in Example 1. Even in any case of Examples 2 to 9 and Comparative Examples 1 to 5, the composition of the piezoelectric thin film matched a Chemical Formula in the following Table 1.

XRD patterns of the piezoelectric thin film of each of Examples 2 to 9 and Comparative Examples 1 to 5 was measured by a similar method as in Example 1. The XRD patterns of any of Examples 2 to 9 and Comparative Examples 1 to 5 also represented that the piezoelectric thin film is composed of a metal oxide having a perovskite structure. Even in any of Examples 2 to 9, the perovskite type oxide contained in the piezoelectric thin film was a tetragonal crystal. Even in any of Examples 2 to 9, a (001) plane of the tetragonal crystal was oriented in a thickness direction of the piezoelectric thin film.

c/a, piezoelectric strain constant d_{33.f}, Young's modulus Y, relative permittivity ε₃₃, dielectric loss (tanδ), resonance frequency fᵣ, and performance index P of each of Examples 2 to 9 and Comparative Examples 1 to 5 were measured or calculated by a similar method as in Example 1. c/a, d_{33.f}, Y, ε₃₃, tanδ, fᵣ, and the performance index P of each of Examples 2 to 9 and Comparative Examples 1 to 5 are shown in the following Table 1.

−e_{31,f} and −e_{31,f}/e₃₃ of each of Example 2 and Comparative Example 1 were measured or calculated by a similar method as in Example 1. −e_{31,f} and −e_{31,f}/e₃₃ of each of Example 2 and Comparative Example 1 are shown in the following Table 2.

TABLE 1

| | | Thickness | | | | | | | Performance |
|---|---|---|---|---|---|---|---|---|---|
| | Composition of | T | fᵣ | d_{33,f} | c/a | ε₃₃ | | Y | index P |
| | piezoelectric thin film | [μm] | [GHz] | [pm/V] | [−] | [−] | tanδ | [GPa] | [−] |
| Comparative | 0.25BKT-0.25BMT-0.50BFO | 10.0 | 0.05 | 93 | 1.14 | 90 | 0.3% | 76 | 82.7% |
| Example 5 | | | | | | | | | |
| Example 9 | 0.25BKT-0.25BMT-0.50BFO | 5.0 | 0.10 | 91 | 1.14 | 89 | 0.3% | 76 | 80.1% |
| Example 3 | 0.25BKT-0.25BMT-0.50BFO | 3.0 | 0.17 | 89 | 1.13 | 89 | 0.3% | 76 | 76.6% |
| Example 1 | 0.25BKT-0.25BMT-0.50BFO | 2.0 | 0.26 | 90 | 1.13 | 87 | 0.4% | 76 | 80.1% |
| Example 4 | 0.25BKT-0.25BMT-0.50BFO | 1.0 | 0.52 | 85 | 1.13 | 98 | 0.6% | 76 | 64.2% |
| Example 5 | 0.25BKT-0.25BMT-0.50BFO | 0.5 | 1.04 | 81 | 1.14 | 107 | 0.7% | 76 | 53.3% |
| Example 6 | 0.45BKT-0.45BMT-0.10BFO | 3.0 | 0.20 | 69 | 1.05 | 135 | 0.4% | 94 | 37.4% |
| Example 2 | 0.45BKT-0.45BMT-0.10BFO | 2.0 | 0.29 | 71 | 1.05 | 129 | 0.4% | 94 | 41.4% |
| Example 7 | 0.45BKT-0.45BMT-0.10BFO | 1.0 | 0.59 | 56 | 1.06 | 140 | 0.7% | 94 | 23.8% |
| Example 8 | 0.45BKT-0.45BMT-0.10BFO | 0.5 | 1.17 | 47 | 1.07 | 155 | 0.9% | 94 | 15.1% |
| Comparative | PZT | 3.0 | 0.20 | 55 | 1.02 | 525 | 1.5% | 118 | 7.6% |
| Example 1 | | | | | | | | | |
| Comparative | PZT | 2.0 | 0.31 | 46 | 1.01 | 588 | 2.0% | 118 | 4.8% |
| Example 2 | | | | | | | | | |
| Comparative | PZT | 1.0 | 0.61 | 32 | 1.01 | 654 | 2.4% | 118 | 2.1% |
| Example 3 | | | | | | | | | |
| Comparative | PZT | 0.5 | 1.22 | 25 | 1.00 | 790 | 3.3% | 118 | 1.0% |
| Example 4 | | | | | | | | | |

TABLE 2

| | | | | | | | Performance | |
|---|---|---|---|---|---|---|---|---|
| | Composition of | d_{33,f} | −e_{31,f} | Y | ε₃₃ | | index P | −e_{31,f}/e₃₃ |
| | piezoelectric thin film | [pm/V] | [C/m²] | [GPa] | [−] | tanδ | [−] | [−] |
| Example 1 | 0.25BKT-0.25BMT-0.50BFO | 90 | 5.2 | 76 | 87 | 0.3% | 80.1% | 0.8 |
| Example 2 | 0.45BKT-0.45BMT-0.10BFO | 71 | 4.4 | 94 | 129 | 0.4% | 41.4% | 0.7 |
| Comparative | PZT | 55 | 11.6 | 118 | 525 | 1.5% | 7.6% | 1.8 |
| Example 1 | | | | | | | | |

### INDUSTRIAL APPLICABILITY

For example, the piezoelectric thin-film element according to an aspect of the invention may be applied to, for example, a piezoelectric transducer, a piezoelectric actuator, and a piezoelectric sensor.

### REFERENCE SIGNS LIST

10: piezoelectric thin-film element, 10a: ultrasonic transducer, 1: single crystal substrate, 2: first electrode layer, 3: piezoelectric thin film, 4: second electrode layer, 5: first intermediate layer, 6: second intermediate layer, DN: normal direction of surface of first electrode layer, dn: thickness direction of piezoelectric thin film (normal direction of surface of piezoelectric thin film), uc: unit cell of metal oxide (tetragonal crystal) having perovskite structure.

1. A piezoelectric thin-film element, comprising:
a first electrode layer;
a piezoelectric thin film stacked on the first electrode layer; and
a second electrode layer stacked on the piezoelectric thin film,
wherein a performance index P of the piezoelectric thin film is defined as (d_{33,f})²×Y/ε,
d_{33,f} is a piezoelectric strain constant of thickness longitudinal vibration of the piezoelectric thin film,
Y is a Young's modulus of the piezoelectric thin film,
ε is a permittivity of the piezoelectric thin film, and
the performance index P is from 10% to 80.1%.

2. The piezoelectric thin-film element according to claim 1,
wherein −e_{31,f}/e₃₃ of the piezoelectric thin film is more than 0 and 0.80 or less.

3. The piezoelectric thin-film element according to claim 1, further comprising:
at least one intermediate layer,
wherein the intermediate layer is disposed between the first electrode layer and the piezoelectric thin film, and
the intermediate layer contains at least one between SrRuO₃ and LaNiO₃.

4. The piezoelectric thin-film element according to claim 1,
wherein the piezoelectric thin film contains a metal oxide having a perovskite structure,
the metal oxide contains bismuth, potassium, titanium, iron, and an element M, and
the element M is at least one element between magnesium and nickel.

5. The piezoelectric thin-film element according to claim 4,
wherein the piezoelectric thin film contains a tetragonal crystal of the metal oxide, and
a (001) plane of the tetragonal crystal is oriented in a thickness direction of the piezoelectric thin film.

6. The piezoelectric thin-film element according to claim 5,
wherein an interval of the (001) plane of the tetragonal crystal is c,
an interval of a (100) plane of the tetragonal crystal is a, and
c/a is from 1.05 to 1.20.

7. The piezoelectric thin-film element according to claim 1,
wherein a thickness of the piezoelectric thin film is from 0.3 μm to 10 μm.

8. The piezoelectric thin-film element according to claim 1,
wherein a resonance frequency of the thickness longitudinal vibration of the piezoelectric thin film is from 0.10 GHz to 2 GHz.

9. A microelectromechanical system, comprising:
the piezoelectric thin-film element according to claim 1.

10. An ultrasonic transducer, comprising:
the piezoelectric thin-film element according to any one of claims 1 to 8 claim 1.
